(19) United States
(12) Patent Application Publication
(10) Pub. No.: US 2008/0042233 A1
(43) Pub. Date: Feb. 21, 2008

(54) SEMICONDUCTOR DEVICE HAVING IMPRIVED ELECTRICAL CHARACTERISTICS AND METHOD OF MANUFACTURING THE SAME

(76) Inventor: Jong-Min Kim, Seoul (KR)

Correspondence Address: SHERR & NOURSE, PLLC, 620 HERNDON PARKWAY, SUITE 200, HERNDON, VA, 20170, US

(21) Appl. No.: 11/832,372

(22) Filed: Aug. 1, 2007

(30) Foreign Application Priority Data
Aug. 17, 2006 (KR) 10-2006-0077455

(51) Int. Cl. H01L 21/22; H01L 29/00

(52) U.S. Cl. 257/519; 438/546; 257/E21.135; 257/E29.001

(57) ABSTRACT

A method of manufacturing a semiconductor device includes forming a pad insulating film over a silicon semiconductor substrate. The pad insulating film and the substrate may be etched to form a trench in the substrate. A thin layer including dopants may be formed over an inner wall of the trench. The dopants may be diffused to an active region from the thin layer. A shallow trench isolation (STI) oxide may fill in the trench. The surface of the STI oxide may then be planarized. Dopants may be uniformly doped into an edge of an active region of a sidewall of an STI along the vertical to suppress a hump phenomenon.

The present application claims priority under 35 U.S.C. 119 to Korean Patent Application No. 10-2006-0077455, filed on Aug. 17, 2006, which is hereby incorporated by reference in its entirety.

### BACKGROUND

An image sensor may be a semiconductor device for converting an optical image into an electrical signal and may be classified into charge coupled device (CCD) image sensors and complementary metal-oxide-silicon (CMOS) image sensors. In a CCD image sensor, a plurality of photodiodes (PDs) for converting an optical signal into an electrical signal are arranged in a matrix. A CCD image sensor includes a plurality of vertical charge coupled devices (VCCD) for transferring charges generated at the PDs in a vertical direction, a horizontal charge coupled device (HCCD) for transferring charges transferred by the VCCD in a horizontal direction, and a sense amplifier for sensing the charges transferred in the horizontal direction and outputting the electrical signal.

However, a CCD may have a complicated driving method and high power consumption. In addition, a CCD may involve complicated manufacturing processes due to a multi-step photolithography process. It may be difficult to integrate a control circuit, a signal processing circuit and an analog/digital (A/D) converter on a CCD chip. Accordingly, it can be difficult to downsize a CCD product.

Recently, CMOS image sensors have been attracting much attention as a next-generation image sensor which overcomes the disadvantages of the CCD. The CMOS image sensor includes MOS transistors formed over a semiconductor substrate in correspondence with unit pixels using a CMOS manufacturing technology. The sensors may use a control circuit and a signal processing circuit as a peripheral circuit, and can employ a switching method for sequentially detecting the outputs of the unit pixels by the MOS transistors. In an CMOS image sensor, since PDs and the MOS transistors are formed in unit pixels, electrical signals of the unit pixels may be sequentially detected by a switching method to display an image. Since a CMOS image sensor uses a CMOS manufacturing technology, a CMOS image sensor may consume less power and require a relatively simple manufacturing process involving a smaller number of photolithography process steps. In a CMOS image sensor, since a control circuit, a signal processing circuit, an analog/digital converter and the like may be integrated onto a CMOS sensor chip, it may be easy to downsize a product. Hence, CMOS image sensors may be used for various applications, including digital still cameras, digital video cameras and the like.

In a CMOS image sensor, a small valley called a divot may be formed in the vicinity of an interface top which is a corner portion between a photodiode of the CMOS image sensor and a STI. A thin gate oxide may be grown over the corner portion. Since a gate poly is selectively etched a poly residue may remain in the divot. This leads to a hump phenomenon in which the divot is turned on before a transistor is turned on, so that a transistor may be turned on twice. Due to the poly residue, a short-circuit between gates may occur. In the CMOS image sensor, the hump phenomenon may occur due to loss of dopants in a sidewall interface of a STI and a STI corner of a gate channel. To suppress the hump phenomenon, a junction depletion region of a photodiode may be separated from the interface of the active region of the sidewall of the STI or an additional doping process may be performed on the edge of the active region.

A method of manufacturing a semiconductor device by imparting dopants into an edge of an active region of a sidewall of a STI will be described with reference to FIGS. 1A to 1F and FIGS. 2A to 2B. As shown in FIG. 1A, a pad oxide film 102 and a pad nitride film 103 may be formed over a silicon semiconductor substrate 101. A portion of the pad nitride film 103 and a portion of the pad oxide film 102 may be selectively etched to expose a portion of the substrate 101, and a predetermined trench 106 may be formed in the substrate 101 using an etching method.

As shown in FIG. 1B, P-type dopants which may include boron may be doped into an inner wall of the trench using, for example, an ion implantation method. As shown in FIG. 1C, a liner oxide film 104 may be formed over the inner wall of the doped trench, using a high-temperature thermal oxidation process. The dopants are diffused to an edge of an active region of the inner wall of the trench by a heating treatment performed in the thermal oxidation process.

As shown in FIG. 1D, a liner oxide film 104 may be formed over the inner wall of the trench before performing an ion implantation process and an additional doping process may be performed with respect to an edge of an active region of the inner wall of the trench using the ion implantation method. That is, ion implantation may be performed before or after the formation of a liner oxide film 104 over the inner wall of the trench.

As shown in FIG. 1E, an insulating material may be used to fill in the oxide lined trench, to form STI 105. The surface of the STI oxide may be planarized using a chemical mechanical polishing (CMP) process.

When the edge of the active region of the sidewall of the STI is doped by the above-described method, ions may also be implanted into the bottom of the STI. These ions may not be removed. As shown in FIG. 1F, when the dopants are implanted into the edge of the active region of the sidewall of the STI at a dose of 5E12, 8E12 or 11E12 ions/cm³, a doping distribution is obtained in which a doping concentration level is relatively low at an upper side and a doping concentration level is relatively high at a lower side in the edge of the active region of the sidewall of the STI. In particular, since the doping concentration level may be relatively low in the vicinity of the upper surface, it may be difficult to obtain a desired effect. Accordingly, it may be necessary to increase a doping concentration level of an upper corner region, in order to suppress a hump phenomenon of the CMOS image sensor.

As shown in FIG. 2A, a pad oxide film and a pad nitride film 202 may be formed over a silicon semiconductor substrate 201. Subsequently, a portion of the pad nitride film and a portion of the pad oxide film 202 may be selectively etched to expose a portion of the substrate 201. A trench may be formed in the substrate 201 using an etching process. An insulating material may fill the trench to form a STI 203. Thereafter, a photoresist film may be coated over the surface of the silicon semiconductor substrate 201 including the STI 203. A photoresist mask 204 may be patterned over the pad oxide film 202 excluding a predetermined region 205. Region 205 may be exposed from the edge of the active region of the sidewall of the STI 203 to the active region of the semiconductor device.

A region excluding the active region covered with the photoresist mask 204 is subjected to an additional doping process, forming an N-well or a P-well. Dopants are implanted into the region excluding the active region covered with the photoresist mask 204 and are diffused. This method may be used where a P-well or an N-well is not formed in the active region.

The method described above uses an ion implantation method to implant the dopants into the upper side and the lower side along to the edge of the active region of the sidewall of the STI. As shown in FIG. 2B, it is difficult to uniformly implant the dopants into the substrate along the vertical axis using an N-well or P-well ion implantation technique. When different photoresist masks are used for forming the STI and for the well ion implantation process, the process becomes complicated. Since a self-alignment is not realized, this method may be unsuitable for highly integrated devices having fine design rules, due to variations in mask alignment.

### SUMMARY

Embodiments relate to a semiconductor device having an improved electrical characteristic and a method of manufacturing the same, and more particularly, to a semiconductor device with a uniform distribution of dopants in a vertical direction along an edge of an active region of a sidewall of a shallow trench isolation (STI) device and a method of manufacturing the same. Embodiments relate to manufacturing highly reliable semiconductor devices by uniformly doping an edge of an active region of a sidewall of a STI along a vertical axis. Embodiments relate to simplifying a process of doping an edge of an active region of a sidewall of a STI to improve yields and to reduce manufacturing costs.

In embodiments, a method of manufacturing a semiconductor device includes forming a pad insulating film over a silicon semiconductor substrate. The pad insulating film and the substrate may be etched to form a trench in the substrate. A thin layer including dopants may be formed over an inner wall of the trench. The dopants may be diffused to an active region from the thin layer. A shallow trench isolation (STI) oxide may fill in the trench. The surface of the STI oxide may then be planarized.

In embodiments, a semiconductor device may include an STI formed in a silicon semiconductor substrate. An active region may be formed in the vicinity of the STI. A plurality of doping level profiles are formed near an edge of an inner wall of the active region along a vertical direction with respect to the substrate.

### DRAWINGS

FIGS. 1A to 1F are cross-sectional views illustrating a method of manufacturing a semiconductor device.

FIGS. 2A to 2B are cross-sectional views illustrating a method of manufacturing a semiconductor device.

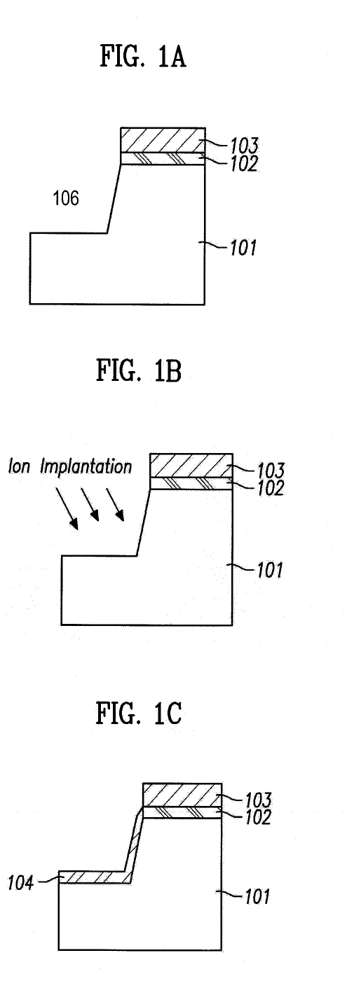

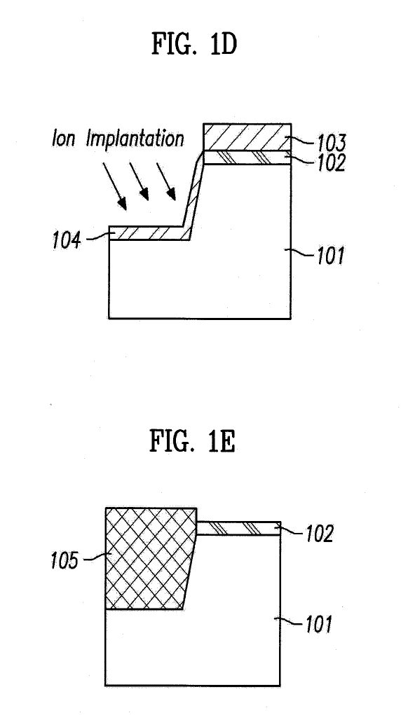

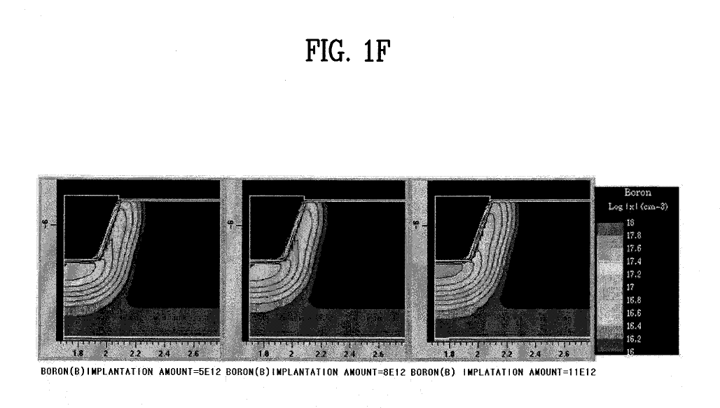

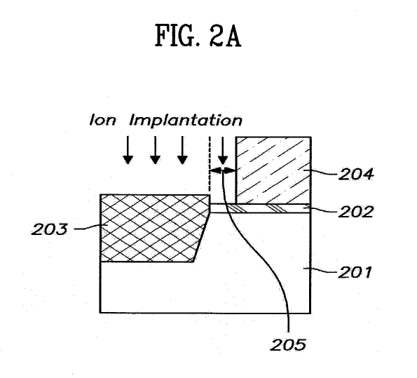

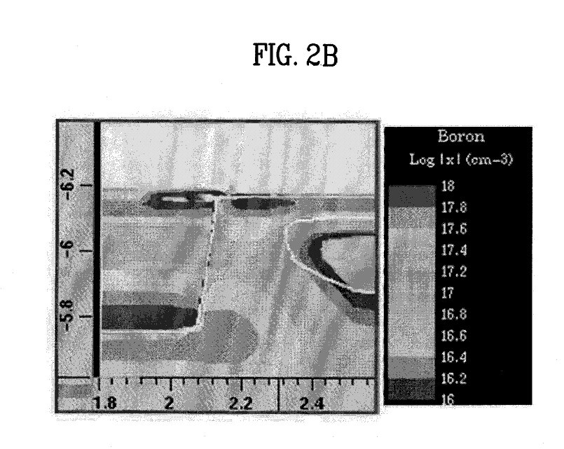

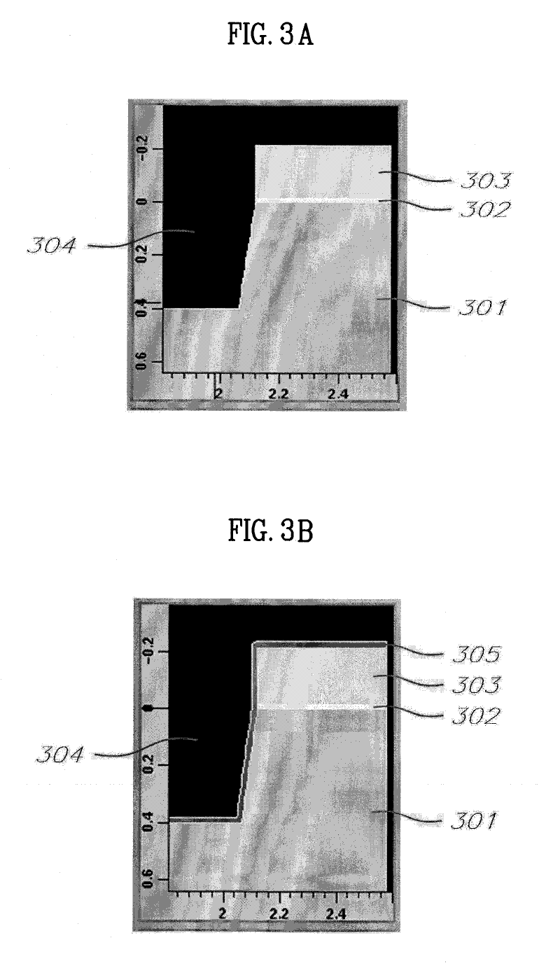

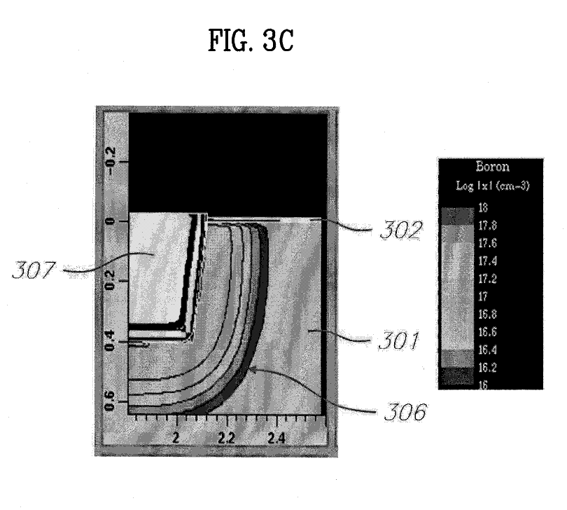

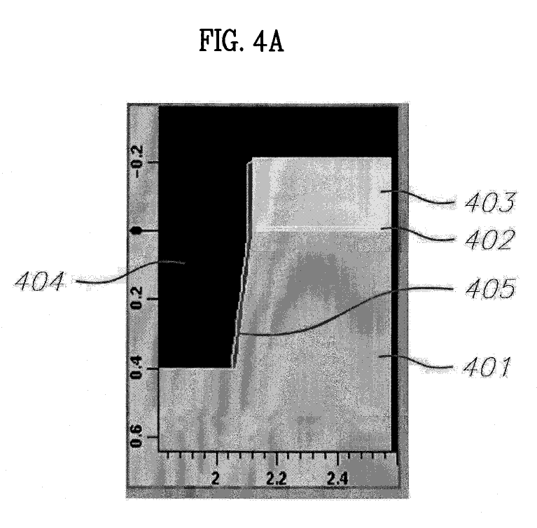

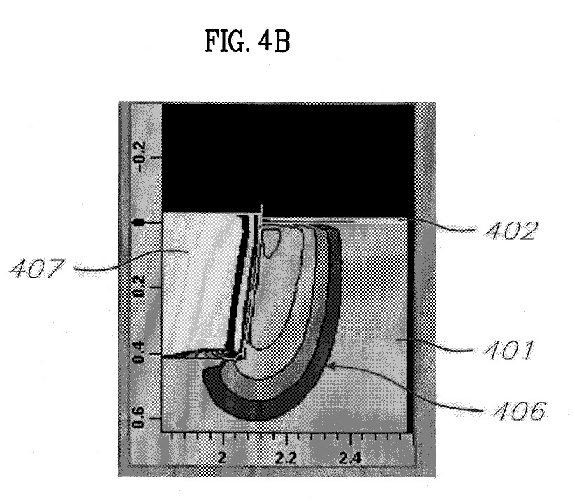

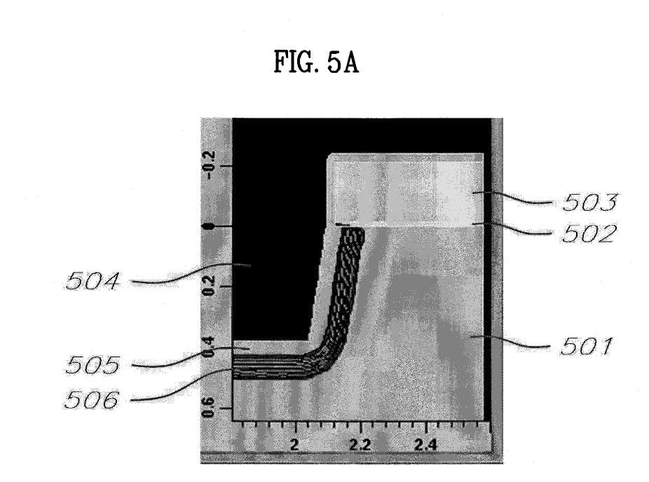

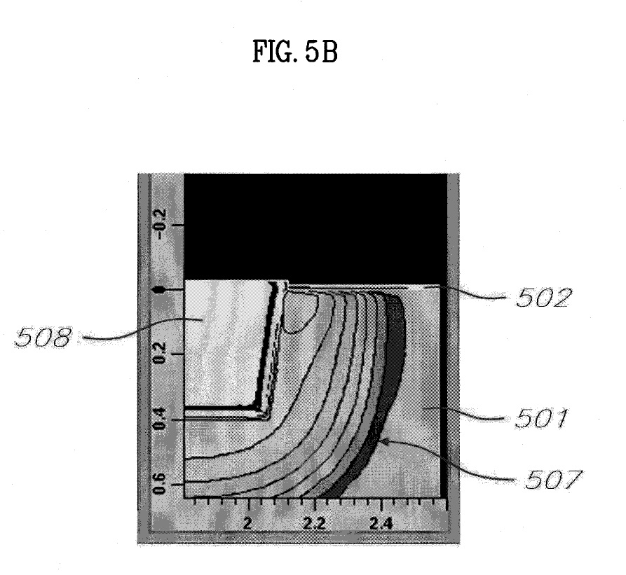

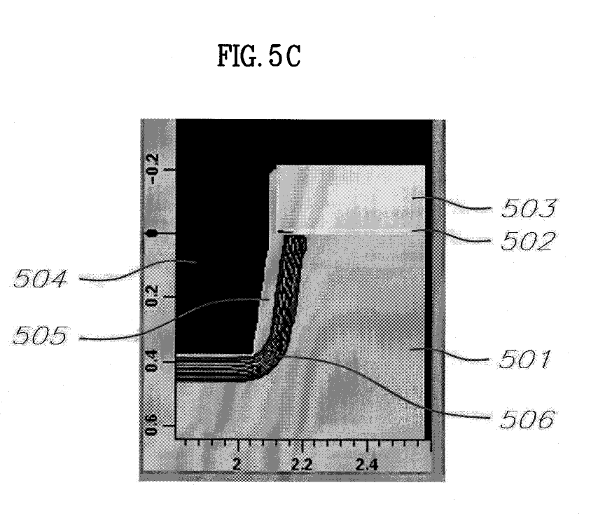

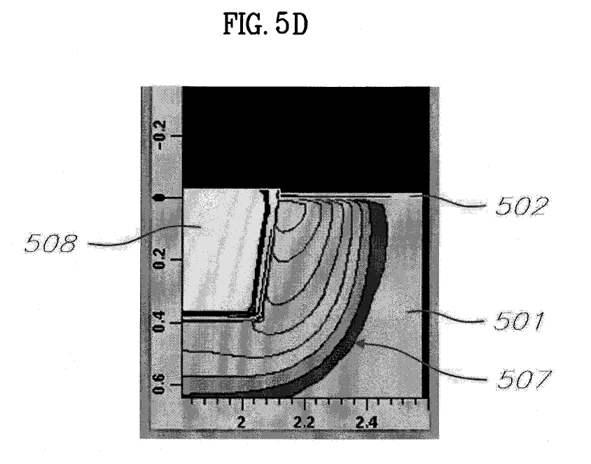

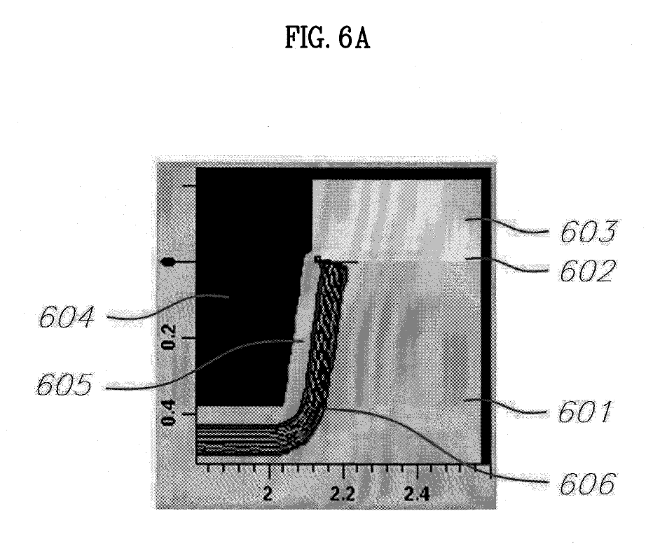

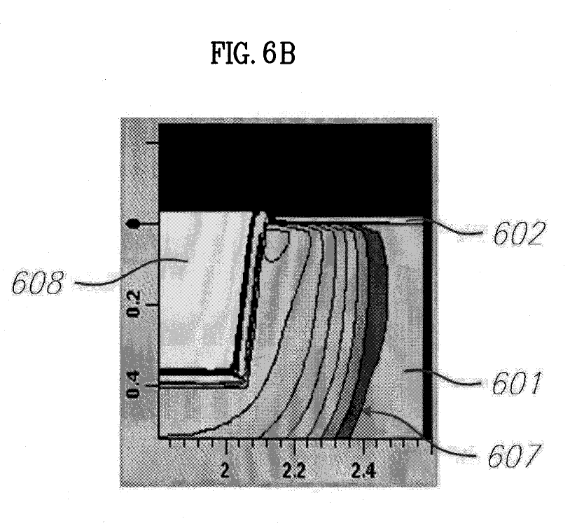

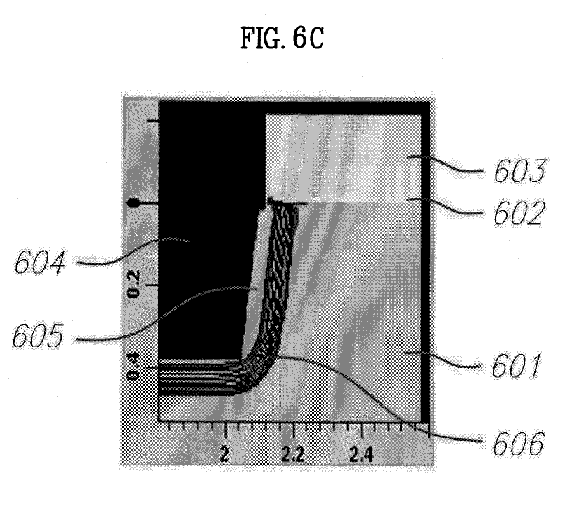

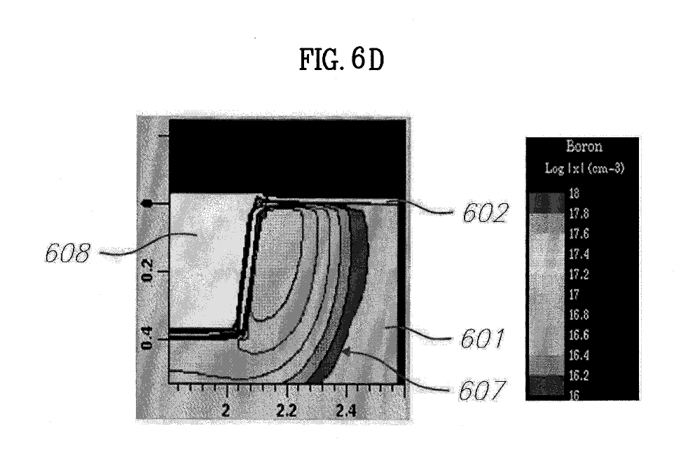

Example FIGS. 3A to 3C are cross-sectional views illustrating a method of manufacturing a semiconductor device, according to embodiments.

Example FIGS. 4A to 4B are cross-sectional views illustrating a method of manufacturing a semiconductor device, according to embodiments.

Example FIGS. 5A to 5D are cross-sectional views illustrating a method of manufacturing a semiconductor device, according to embodiments.

Example FIGS. 6A to 6D are cross-sectional views illustrating a method of manufacturing a semiconductor device, according to embodiments.

### DESCRIPTION

As shown in example FIG. 3A, a pad oxide film 302 and a pad nitride film 303 may be formed over a silicon semiconductor substrate 301, according to embodiments. The pad nitride film 303 and the pad oxide film 302 may be selectively etched to expose a portion of the semiconductor substrate. An exposed portion of the semiconductor substrate may be etched using the selectively etched pad insulating film as a mask to form a trench 304.

As shown in example FIG. 3B, polysilicon may be deposited over the inner wall of the trench 304 formed in the silicon semiconductor substrate 301, in accordance with embodiments. While the polysilicon is deposited over the inner wall of the trench 304, p-type dopants or N-type dopants including boron (B) or phosphorus (P) may be doped into the polysilicon layer, thereby forming a doped polysilicon thin layer 305. The doped polysilicon thin layer 305 may be formed over the edge of an active region of the inner wall of the trench 304 and may have a thickness in the range of 100 Å to 700 Å.

As shown in example FIG. 3C, O₂ gas may be injected into the inner wall of the trench 304 such that the doped polysilicon thin layer 305 formed by the above-described method chemically reacts with the O₂ gas in a high-temperature thermal oxidation process, in accordance with embodiments. A liner oxide film (SiO₂) may be formed by the chemical reaction between the doped polysilicon thin layer 305 and the O₂ gas. The dopants included in the doped polysilicon thin layer 305 may be diffused into the active region due to a concentration difference between the dopants and silicon material which constitutes the inner wall of the trench 304 during a heat treatment in the thermal oxidation process. A plurality of doping level profiles 306 is formed from the edge of the sidewall of the STI to the active region. In the plurality of doping level profiles 306, an upper doping level profile and a lower doping level profile of the edge of the active region of the sidewall of the STI may have a substantially identical concentration distribution. An insulating material may fill in the trench 304, which is subjected to the liner oxidation process and the doping process, to form a STI 307. The surface of the STI oxide 307 may be planarized by a CMP process.

As illustrated in example FIG. 4A, a trench 404 may be formed in a silicon semiconductor substrate 401, in accordance with embodiments. A doped polysilicon thin layer 405 may be formed. The doped polysilicon thin layer 405 may be anisotropically etched, so that the doped polysilicon thin layer 405 remains only in the edge of the active region of the sidewall of the trench 404 excluding the pad nitride film 403, and the bottom of the trench 404.

As shown in example FIG. 4B, O₂ gas may be injected into the inner wall of the trench 404 such that the doped polysilicon thin layer 405 chemically reacts with the 02 gas in a high-temperature thermal oxidation process, in accordance with embodiments. Accordingly, it may be possible to form SiO₂ over the edge of the active region of the sidewall of the trench 404 by the chemical reaction between the doped polysilicon thin layer 405 and the O₂ gas. The dopants included in the doped polysilicon thin layer 405 may be diffused to the active region due to a concentration difference between the dopants and silicon material which constitutes the inner wall of the trench 404 by the high temperature of the thermal oxidation process. Accordingly, a plurality of doping level profiles 406 is formed from the edge of the sidewall of the STI to the active region. An insulating material may fill in the trench 404, which may be subjected to the liner oxidation process and the doping process, thereby forming a STI 407. Thereafter, the surface of the STI oxide 407 may be planarized by a CMP process.

In embodiments, since dopants can be more uniformly implanted along the vertical direction, the upper doping level profile of the sidewall of the STI 407 may be adjusted to be higher than the lower doping level profile in view of the concentration distribution.

In a CMOS image sensor, since the doping concentration of the silicon semiconductor substrate may be lower than that of the edge of the active region of the sidewall of the STI, current leakage, a hump phenomenon caused by out-diffusion of dopants into the vicinity of the STI, and/or concentration of electric field can be suppressed. Accordingly, since the doping concentration level of the lower doping level profile of the sidewall of the STI may be relatively low, it is possible to compensate the upper corner portion of the sidewall of the STI while suppressing the electric field reinforcement of a source/drain junction.

As illustrated in FIG. 5A, the processes up to the process of forming a trench 504 in a silicon semiconductor substrate 501 may be the same as described in the above examples. An epitaxial thin layer may be grown up to the inner wall of the trench 504. A pad nitride film 503 may be used as a mask using an epitaxial growth method such as a vapor phase epitaxial (VPE) growth method. The epitaxial thin layer may be grown by injecting O₂ gas or by epitaxially growing a single crystal material excluding Si over a silicon semiconductor single crystal substrate using a hetero epitaxial growth method. P-type dopants or N-type dopants including, for example, boron or phosphorous may be doped into the epitaxial thin layer during the epitaxial growth process to form a doped epitaxial thin layer 505. While the epitaxial thin layer is grown, dopants 506 may be gradually diffused toward the active region of the inner wall of the trench 504.

As illustrated in example FIG. 5B, dopants 506 which are gradually diffused are further diffused toward the active region of the inner wall of the trench by a heat treatment of the process of growing the epitaxial thin layer, thereby forming a plurality of doping level profiles 507, in accordance with embodiments. An insulating material may fill in the trench 504 to form an STI 508. The surface of the STI oxide 508 may be planarized by a CMP process. The dopant concentration may be determined by the dose of the dopants in the epitaxial thin layer and the thickness of the epitaxial thin layer.

Accordingly, the upper doping level profile of the edge of the active region of the sidewall of the STI may be higher than the lower doping level profile of the edge of the active region, as well as the bottom of the sidewall of the STI, due to the doping concentration distribution.

As illustrated in example FIG. 5C, the previously doped epitaxial thin layer 505, which is grown over the inner wall of the trench 504 and the pad nitride film 503 used as the mask, may be anisotropically etched in the vertical direction to form the doped epitaxial thin layer 505 only over the edge of the active region of the sidewall of the trench 504, in accordance with embodiments. The doping concentration of the upper side and the lower side of the edge of the active region of the sidewall of the STI may be adjusted by adjusting the thickness of the doped epitaxial thin layer 505. P-type dopants or N-type dopants including boron or phosphorous may be doped into the epitaxial thin layer during the epitaxial thin layer growth process to form a doped epitaxial thin layer 505. While the epitaxial thin layer is grown, dopants 506 may be gradually diffused toward the active region of the inner wall of the trench 504.

As illustrated in example FIG. 5D, dopants 506 are further diffused toward the active region of the inner wall of the trench by a heat treatment of the process of growing the epitaxial thin layer, thereby forming a plurality of doping level profiles 507, in accordance with embodiments. An insulating material may fill in the trench 504 to form the STI 508. The surface of the STI oxide 508 may be planarized by a CMP process.

Accordingly, compared with the hetero epitaxial method illustrated in example FIGS. 5A and 5B, the upper doping level profile of the sidewall of the STI may be higher than that of the lower doping level profile of the sidewall of the STI due to the doping concentration distribution.

As illustrated in example FIG. 6A, the processes up to forming a trench 604 in a silicon semiconductor substrate 601 may be similar to embodiments described above. An epitaxial thin layer may be grown only over a silicon (Si) region of the inner wall of the trench 604 using, for example, SiH₄ gas using a homo epitaxial growth method including a VPE growth method. The injected SiH₄ gas grows substantially single crystal silicon (Si) over the silicon semiconductor single crystal substrate using epitaxial method, and hydrogen (H) gas is dissipated. Dopants are imparted into the epitaxial thin layer during the epitaxial growth process to form a doped epitaxial thin layer 605. While the epitaxial thin layer is grown, dopants 606 may be gradually diffused toward the edge of the active region of the inner wall of the trench 604.

As illustrated in example FIG. 6B, dopants 606 may be further diffused toward the active region of the inner wall of the trench by a heat treatment during the process of growing the epitaxial thin layer to form a plurality of doping level profiles 607, in accordance with embodiments. An insulating material may fill in the trench 604 to form a STI 608. The oxide surface of the STI 608 may be planarized by a CMP process. The dopant concentration may be determined by a dopant dose in the epitaxial thin layer and the thickness of the epitaxial thin layer.

Accordingly, the upper doping level profile of the active region of the sidewall of the STI may be slightly higher than the lower doping level profile of the active region of the sidewall of the STI, but the doping level profile characteristic of the upper area of the active region is almost same to that of the lower area of the active region.

As illustrated in example FIG. 6C, the sidewall including the bottom of the trench 604, that is, the epitaxial thin layer grown only in a silicon region, may be anisotropically etched in the vertical direction, in accordance with embodiments. P-type dopants or N-type dopants including boron or phosphorous may be added into the epitaxial thin layer during an epitaxial growth process to form a doped epitaxial thin layer 605. While the epitaxial thin layer is grown, dopants 606 may be gradually diffused toward the active region of the inner wall of the trench 604.

As illustrated in example FIG. 6D, dopants 606 may be further diffused toward the active region of the inner wall of the trench by a heat treatment of the process of growing the epitaxial thin layer, thereby forming a plurality of doping level profiles 607, in accordance with embodiments. An insulating material may fill in the trench 604 to form the STI 608. The surface of the STI oxide 608 may be planarized by a CMP process.

Accordingly, when compared with the homo epitaxial method described with reference to FIGS. 6A and 6B, the upper doping level profile of the sidewall of the STI is relatively higher than the lower doping level profile of the sidewall of the STI and a relatively uniform doping concentration profile may be obtained.

According to embodiments, since a dopant concentration profile in an edge of an active region of a sidewall of a STI may be substantially uniform along a vertical direction so as to suppress a hump phenomenon, it is possible to manufacture a semiconductor device having an improved electrical characteristic and improved reliability. Since a mask manufacturing step may be simplified when the edge of the active region of the sidewall of the STI is doped, it is possible to manufacture a self-aligned semiconductor device, improving yield, and reducing manufacturing cost.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a pad insulating film over a silicon semiconductor substrate;
etching the pad insulating film and the substrate and forming a trench in the substrate; and
forming a thin layer including dopants over an inner wall of the trench and diffusing the dopants from the thin layer to an active region.

2. The method of claim 1, wherein the forming of the thin layer including the dopants and the diffusing of the dopants comprises:
forming a polysilicon thin layer including the dopants over an edge of the active region of the inner wall of the trench;
performing a shallow trench isolation liner oxidation process with respect to the doped polysilicon thin layer; and
diffusing the dopants into the active region by a heat treatment during the shallow trench isolation liner oxidation process.

3. The method of claim 1, wherein the forming of the thin layer including the dopants and the diffusing of the dopants comprises:
forming a polysilicon thin layer including dopants over an edge of the active region of the inner wall of the trench;
performing an anisotropic etching process with respect to the doped polysilicon thin layer in a vertical direction;
performing a shallow trench isolation liner oxidation process with respect to the etched polysilicon thin layer; and
diffusing the dopants into the active region by a heat treatment during the shallow trench isolation liner oxidation process.

4. The method of claim 1, wherein the forming of the thin layer including the dopants and the diffusing of the dopants comprises:
growing an epitaxial thin layer over the inner wall of the trench;
adding the dopants into the epitaxial thin layer, thereby forming a doped epitaxial thin layer, while the epitaxial thin layer is grown; and
diffusing the dopants into the active region by a heat treatment.

5. The method of claim 1, wherein the forming of the thin layer including the dopants and the diffusing of the dopants comprises:
growing an epitaxial thin layer over the inner wall of the trench;
adding the dopants into the epitaxial thin layer, thereby forming a doped epitaxial thin layer, while the epitaxial thin layer is grown;
performing an anisotropic etch on the doped epitaxial thin layer in a vertical direction; and
diffusing the dopants into the active region by a heat treatment.

6. The method of claim 4, wherein the doped epitaxial thin layer is grown using a hetero epitaxial growth method.

7. The method of claim 5, wherein the doped epitaxial thin layer is grown using a hetero epitaxial growth method.

8. The method of claim 1, wherein the forming of the thin layer including the dopants and the diffusing of the dopants comprises:
injecting reactive raw gas including SiH₄ gas into the inner wall of the trench and growing an epitaxial thin layer only in a silicon region of the trench;
adding the dopants into the epitaxial thin layer, thereby forming a doped epitaxial thin layer, while the epitaxial thin layer is grown; and
diffusing the dopants into the active region by a heat treatment.

9. The method of claim 8, wherein the epitaxial thin layer comprises a single crystal material.

10. The method of claim 1, wherein the forming of the thin layer including the dopants and the diffusing of the dopants comprises:
injecting reactive raw gas including SiH₄ gas into the inner wall of the trench and growing an epitaxial thin layer only in a silicon region of the trench;
adding the dopants into the epitaxial thin layer, thereby forming a doped epitaxial thin layer, while the epitaxial thin layer is grown;
performing an anisotropic etch on the doped epitaxial thin layer in a vertical direction; and
diffusing the dopants into the active region by a heat treatment.

11. The method of claim 10, wherein the epitaxial thin layer comprises a single crystal material.

12. The method of claim 8, wherein the doped epitaxial thin layer is grown using a homo epitaxial growth method.

13. The method of claim 10, wherein the doped epitaxial thin layer is grown using a homo epitaxial growth method.

14. The method of claim 1, comprising:
filling a shallow trench isolation oxide into the trench.

15. The method of claim 14, comprising:
planarizing the surface of the shallow trench isolation oxide.

16. An apparatus comprising:
a shallow trench isolation formed in a silicon semiconductor substrate;
an active region formed in the vicinity of the shallow trench isolation; and
a plurality of doping level profiles formed from an edge of an inner wall of the active region in a vertical direction of the substrate.

17. The apparatus of claim 16, wherein the plurality of doping level profiles extend from the edge of the sidewall of the shallow trench isolation to the active region, and an upper region doping level profile and a lower region doping level profile are formed to have a substantially identical doping concentration distribution.

18. The apparatus of claim 16, wherein the plurality of doping level profiles extend from the edge of the sidewall of the shallow trench isolation to the active region, and doping concentration in an upper region is greater than doping concentration in a lower region.

19. The apparatus of claim 16, comprising an epitaxial thin layer formed over the sidewall of the shallow trench isolation.

20. The apparatus of claim 19, wherein the epitaxial thin layer comprises a single crystal material.
